(19) United States
(12) Patent Application Publication
(10) Pub. No.: US 2010/0278600 A1
(43) Pub. Date: Nov. 4, 2010

(54) SUPPORT BOARD FOR PERFORATION PROCESSING AND METHOD OF PERFORATION PROCESSING

(75) Inventors: Shingo Kaburagi, Tokyo (JP); Yoshikazu Uda, Tokyo (JP); Koji Okura, Isehara-shi (JP); Yasuyuki Uraki, Isehara-shi (JP); Tatsuhiro Mizo, Oyama-shi (JP)

Correspondence Address: ATTN: Stephen B. Parker (WPD);Westerman, Hattori, Daniels & Adrian, LLP, 1250 Connecticut Ave., Suite 700, Washington, DC, 20036, US

(73) Assignees: OHTOMO CHEMICAL INS., CORP., Tokyo (JP); SHOWA DENKO PACKAGING CO., Isehara-shi (JP); SHOWA DENKO K.K., Tokyo (JP)

(21) Appl. No.: 12/445,293

(22) PCT Filed: Oct. 10, 2007
(86) PCT No.: PCT/JP2007/069773

§ 371 Date: Jun. 18, 2010

(30) Foreign Application Priority Data
Oct. 12, 2006 (JP) 2006-279026
Oct. 10, 2007 (JP) PCT/JP2007/069773

(51) Int. Cl. B23B 49/00; H05K 3/00

(52) U.S. Cl. 408/1 R; 408/241 G

(57) ABSTRACT

The support board for perforation processing 1 of the present invention having a lubrication layer 3 formed on at least one surface of an aluminum substrate 2 is characterized in that the lubrication layer 3 is made of a mixture containing crystalline water-soluble resin and crystal nucleation agent. This structure provides a support board for perforation processing having a lubrication layer excellent in adherence to an aluminum substrate, free from stickiness, and excellent in blocking prevention, and capable of easily being washed after processing.

### TECHNICAL FIELD

The present invention relates to a support board used for forming small diameter perforations in workpieces, e.g., for forming through-holes in printed circuit boards, and a method of perforation processing using the support board.

In this specification and claims, the word “aluminum” is used to include the meaning of pure aluminum and aluminum alloy. Also, in this specification and claims, the word “board” includes the meaning of a foil as well.

### BACKGROUND ART

Conventionally, when performing perforation processing of a through-hole in a printed circuit board, the following method is employed. That is, a plurality of printed circuit raw boards are stacked on a back-up board, and an aluminum support board is disposed on the upper surface of the uppermost raw board. In this state, perforation processing of the printed circuit raw boards is executed by making a drill penetrate the support board from above to form through-holes in all of the stacked boards at a time. This support board is used for improving the biting of the drill and preventing occurrence of damages on the board's surface and/or generation of burrs at the periphery of the perforation at the time of processing.

In the recent years, in accordance with the density growth of printed circuit boards, it is required to form a small diameter hole having a diameter of 0.3 mm or less. To cope with such a demand, if perforation processing is performed using an aluminum board as a support board and a small diameter drill having a diameter of 0.3 mm or less, the drill tends to slip sideways on the surface of the support board. This results in deteriorated positioning accuracy of the perforation processing, frequent drill breakage, and a rough inner circumferential surface of the perforation.

Furthermore, the number of printed circuit raw boards to be stacked cannot be increased to prevent breakage of drills, which results in insufficient improvement of the processing efficiency.

Under the circumstances, it has been proposed to use a support board for perforation processing in which, on at least one surface of an aluminum substrate, a water soluble lubrication sheet having a thickness of 0.1 to 3 mm made of a mixture of 20 to 90 weight % of polyethylene glycol having a molecular mass of more than 10,000 and 80 to 10 weight % of water soluble lubrication agent is disposed (see Patent Document 1).

Furthermore, it has also been proposed to use, as the water soluble lubrication sheet, a sheet having a thickness of 0.02 to 3 mm made of a mixture of 20 to 90 weight % of polyether ester and 80 to 10 weight % of water soluble lubricant (see Patent Document 2).

Patent Document 1: Japanese Laid-open Unexamined Patent Publication No. H4-92494

Patent Document 2: Japanese Laid-open Unexamined Patent Publication No. H6-344297

### DISCLOSURE OF THE INVENTION

### Problems to be Solved by the Invention

The technology as disclosed by the aforementioned Patent Document 1, however, has problems that the operations for forming the water-soluble lubrication sheet are difficult since the mixture is poor in film formation, the water-soluble lubrication sheet easily breaks, and the water-soluble lubrication sheet is sticky. The stickiness makes the handling of the water-soluble lubrication sheet difficult since it makes the hands sticky, and easily causes blocking. Once blocking occurs, in cases where a plurality of support boards have been stored in a stacked manner, the adjacent boards adhere with each other, which greatly deteriorates the workability of detaching the support boards one by one at the time of use. Furthermore, when detaching each support board when used, there have been problems that the lubricant of one of the two adjacent support boards adheres to the other support board and comes off, causing an uneven thickness of the water-soluble lubrication sheet and an irregular surface of the lubrication sheet to be brought into direct contact with the raw board, which in turn results in breakage of drills and/or deteriorated positioning accuracy of perforation processing. Also, in the case of storing a long support board in a wound manner, the adjacent support boards may adhere with each other due to blocking, which makes it difficult to unwind the support board when used.

Furthermore, the water-soluble lubrication sheet disclosed by the aforementioned Patent Document 2 has problems that the adhesiveness to the aluminum substrate is insufficient and therefore the water-soluble lubrication sheet may partly detach from the aluminum substrate and warp. Furthermore, the water-soluble lubrication sheet is sticky and easily causes blocking, which also causes the same problems as in Patent Document 1. If the thickness of the water-soluble lubrication sheet is set to 0.2 mm or more, the lubrication sheet cannot be removed by water washing after the perforation processing, which necessitates hot-water washing. This is troublesome.

The present invention was made in view of the aforementioned technical backgrounds, and aims to provide a support board for perforation processing having a lubrication layer excellent in adhesiveness to an aluminum substrate, less sticky, excellent in blocking prevention, and capable of being easily washed after processing, and also aims to provide a method of perforation processing capable of reducing occurrence of drill breakage and improving the perforation positioning accuracy.

The other objects of the present invention will be apparent from the following embodiments of the present invention.

### Means to Solve the Problems

The present invention provides the following means to attain the aforementioned objects.

[1] A support board for perforation processing having a lubrication layer formed on at least one surface of an aluminum substrate,

wherein the lubrication layer is made of a mixture containing crystalline water-soluble resin and crystal nucleation agent.

[2] The support board for perforation processing as recited in the aforementioned Item 1, wherein the crystal nucleation agent is one or more types of nucleation agents selected from the group consisting of sorbitol series nucleation agent, organic phosphate series nucleation agent, carboxylic acid metal salt series nucleation agent, rosin series nucleation agent, organic acid series nucleation agent, polymer series nucleation agent and inorganic compound series nucleation agent.

[3] The support board for perforation processing as recited in the aforementioned Item 1 or 2, wherein the lubrication layer is made of a mixture containing 0.01 to 5 mass parts of the crystal nucleation agent with respect to 100 mass parts of the water-soluble resin.

[4] The support board for perforation processing as recited in any one of the aforementioned Items 1 to 3, wherein a thickness of the lubrication layer is 0.01 to 3 mm.

[5] The support board for perforation processing as recited in any one of the aforementioned Items 1 to 4, wherein, as the water soluble resin, one or more types of water soluble resins selected from the group consisting of polyoxyethylene, polyoxyethylene propylene copolymer, and derivatives thereof are used.

[6] A method of perforation processing, wherein, in a state in which the support board for perforation processing as recited in any one of aforementioned Items 1 to 5 is disposed on top of a plurality of stacked printed circuit boards, a perforation having a diameter of 0.3 mm or less is formed in the support board and the printed circuit raw boards from above using a drill.

### EFFECTS OF THE INVENTION

According to the invention [1], the lubrication layer formed on at least one surface of the aluminum substrate is made of a mixture in which crystal nucleation agent is mixed in water-soluble resin. Therefore, the lubrication layer is excellent in adhesiveness to an aluminum substrate and has sufficient durability. Further, the lubrication layer is free from stickiness and also excellent in blocking prevention, and can sufficiently prevent occurrence of breakage of the lubrication layer. Also, it can be easily dissolved and removed by water washing after perforation processing. As mentioned above, the support board for perforation processing according to the present invention is free from stickiness and excellent in blocking prevention, and therefore breakage of drills at the time of perforation processing can be reduced and perforation positioning accuracy can be improved.

It is considered that the crystal nucleation agent acts as a nucleation agent for crystals when the water-soluble resin crystallizes to finely divide the crystal grains of the water-soluble resin. And it is assumed that the generation of these minute crystals of the resin improves the surface flatness of the lubrication layer, the prevention of stickiness, and the blocking prevention.

According to the invention [2], as the crystal nucleation agent, one or more types of nucleation agents selected from the group consisting of sorbitol series nucleation agent, organic phosphate series nucleation agent, carboxylic acid metallic salt series nucleation agent, rosin series nucleation agent, organic acid series nucleation agent, polymer series nucleation agent and inorganic compound series nucleation agent are used. Therefore, the stickiness prevention and blocking prevention can be further improved.

According to the invention [3], since the lubrication layer is made of a mixture containing 0.01 to 5 mass parts of crystal nucleation agent with respect to 100 mass parts of water-soluble resin, the crystal nucleation agent can be evenly dispersed in the lubrication layer, and a lubrication layer free from stickiness and excellent in blocking prevention nature can be formed.

According to the invention [4], since the thickness of the lubrication layer is 0.01 to 3 mm, it is possible to form a lubrication layer free from stickiness and excellent in blocking prevention nature and capable of sufficiently preventing the phenomenon that the lubrication layer components twist around the drill bits.

According to the invention [5], since one or more types of water-soluble resins selected from the group consisting of polyoxyethylene, polyoxyethylene propylene copolymer, and derivatives thereof are used, the water-solubility of the lubrication layer can be improved, which can further improve the dissolution and removal nature of the lubrication layer components at the time of water washing to be executed after perforation processing.

According to the invention [6], when forming a perforation 0.3 mm or less in diameter at once in a plurality of stacked printed circuit raw boards, occurrence of breakage of drills can be reduced and the perforation positioning accuracy can be improved as well.

### BRIEF EXPLANATION OF THE DRAWINGS

FIG. 1 is a cross-sectional view showing an embodiment of a support board for perforation processing according to the present invention.

### DESCRIPTION OF THE REFERENCE NUMERALS

1 . . . support board for perforation processing
2 . . . aluminum substrate
3 . . . lubrication layer

### BEST MODE FOR CARRYING OUT THE INVENTION

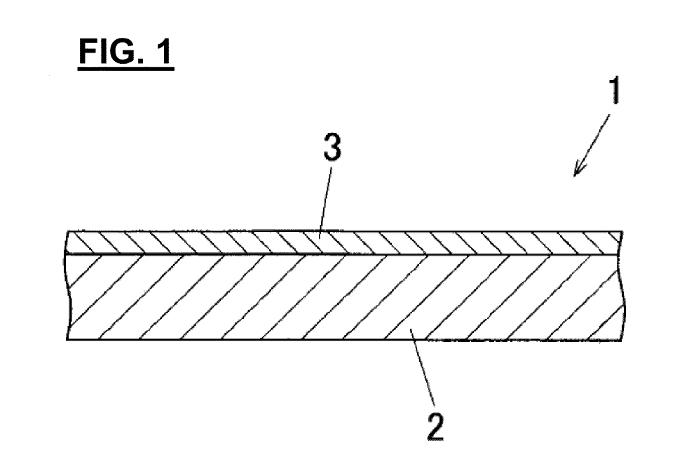

FIG. 1 shows an embodiment of the support board 1 for perforation processing according to the present invention. The support board 1 for perforation processing is provided with an aluminum substrate 2 having a lubrication layer 3 on one surface of the substrate.

Although the aluminum substrate 2 is not specifically limited, as examples thereof, a flexible aluminum board, a semihard aluminum board, and a hard aluminum board can be exemplified. The thickness of the aluminum substrate 2 is preferably set to 50 and 500 μm. The thickness set to 50 μm or more can prevent the occurrence of burrs on the board 2, and the thickness set to 500 μm or less can improve the discharging nature of chips or shavings generated at the time of the perforation processing. The surface of the aluminum substrate 2 on which the lubrication layer 3 is formed is preferably subjected to a surface treatment (for example, primer treatment, or precoat treatment) to strengthen the adhesiveness to the lubrication layer 3.

The lubrication layer 3 is made of a mixture containing water-soluble resin and crystal nucleation agent. Since the lubrication layer 3 is made of a mixture containing crystalline water-soluble resin and crystal nucleation agent, the lubrication layer 3 has excellent adhesiveness to the aluminum substrate 2 and provides sufficient durability. It is also free from stickiness and excellent in blocking prevention nature, and sufficiently prevents the occurrence of breakage of the lubrication layer 3. Furthermore, the dissolution and removal of the lubrication layer components can be easily performed by water washing after perforation processing.

It is considered that the crystal nucleation agent acts as crystal water-soluble resin when the water-soluble resin crystallizes to finely divide the crystal grains of the water-soluble resin and that the minute crystals of the resin improves the surface flatness, the stickiness prevention and the blocking prevention of the lubrication layer.

The water-soluble resin is not specifically limited, but can be polyethylene glycol, polyethylene oxide, polypropylene glycol, polytetramethylene glycol, polypropylene oxide, or glycols of copolymers thereof, and also can be a resin obtained by reacting a polymer substance of ethylene oxides and a compound (e.g., phthalic acid, isophthalic acid, terephthalic acid, sebacic acid, dimethyl esters of these acids, diethyl ester of these acids, pyromellitic dianhydride, etc.) selected from the group consisting of polyvalent carboxylic acid, acid anhydrides and esters thereof. A mixture of the aforementioned one or more types can be used.

Among these resins, one or more types of water-soluble resins selected from the group consisting of polyoxyethylene, polyoxyetheylene propylene copolymer and derivatives thereof are preferably used. These specified water-soluble resins have good solubility in water, and therefore the water solubility of the lubrication layer 3 can be further improved. As a result, in the case of using the specified water-soluble resin, the components of the lubrication layer adhered to the printed circuit raw board can be easily removed by water washing.

The crystal nucleation agent (also referred to as “nucleation agent”) is not specifically limited, and can be any substance that can increase the crystallizing speed of the crystalline water-soluble resin by addition of it. However, the crystal nucleation agent is not specifically limited, but can be preferably one or more types of nucleation agents selected from the group consisting of sorbitol series nucleation agent, organic phosphate series nucleation agent, carboxylic acid metallic salt series nucleation agent, rosin series nucleation agent, organic acid series nucleation agent, polymer series nucleation agent and inorganic compound series nucleation agent. In the case of using these nucleation agents, stickiness prevention and blocking prevention can be improved. In addition, as the inorganic compound nucleation series agent, it is preferably to mix fine powder 3 μm or less.

The sorbitol series nucleation agent is not specifically limited, but for example, can be dibenzylidene sorbitol, tribenzylidene sorbitol, bis-sorbitol, chlor substituted dibenzylidene sorbitol, alkyl substituted dibenzylidene sorbitol, bis-(p-ethyl benzylidene) sorbitol, or bis-(p-methyl benzylidene) sorbitol.

The organic phosphate nucleation agent is not specifcally limited, but can be, for example, bis sodium methylene bis-acid phosphate sodium salt, diphosphate, sodium 2,2′-methylene bis(4,6-di-tert-butylphenyl) phosphate, or sodium di(4-tert-butylphenyl) phosphate.

The carboxylic metallic salt series nucleation agent is not specifically limited, but for example, can be sodium stearate, sodium benzoate, sodium salt of ethylene-acrylic acid copolymer, and sodium salt of styrene-acrylic acid copolymer.

The rosin nucleation agent is not specifically limited, but for example, can be rosin metal salt, such as, e.g., PINE CRYSTAL MK-1500 manufactured by Arakawa Chemical Industries, LTD).

The organic acid series nucleation agent is not specifically limited, but for example, can be carboxylic acid, such as, e.g., adipic acid or benzoic acid. In addition, the terms “organic acid” and “carboxylic acid” is used not to include the meaning of amino acid.

The polymer series nucleation agent is not specifically limited, but can be, for example, polyethylene, polypropylene, polybutene, and polystyrene.

The inorganic compound series nucleation agent is not specifically limited, but can be, for example, talc, silica, calcium carbonate, titanium dioxide, and magnesium oxide.

The lubrication layer 3 is preferably made of a mixture containing 0.01 to 5 mass parts of the crystal nucleation agent with respect to 100 mass parts of the water-soluble resin. By containing 0.01 mass parts or more of crystal nucleation agent with respect to 100 mass parts of water-soluble resin, the aforementioned various effects (adhesiveness improving effect, stickiness prevention effect, blocking prevention effect) can be sufficiently ensured. By containing 5 mass parts or less of crystal nucleation agent to 100 mass parts of water-soluble resin, the crystal nucleation agent can be sufficiently dispersed evenly in the resin. Among other things, it is more preferable that the lubrication layer 3 is made of a mixture containing 0.02 to 3 mass parts of the crystal nucleation agent with respect to 100 mass parts of the water-soluble resin.

It is preferable that the thickness of the lubrication layer 3 is set to 0.01 to 3 mm. If it is 0.01 mm or more, the aforementioned effects (adhesiveness improving effect, stickiness prevention effect, blocking prevention effect) can be sufficiently ensured. If it is 3 mm or less, the lubrication layer component can be effectively prevented from winding around the drill bits. It is more preferable that the thickness of the lubrication layer 3 is set to 0.02 and 0.50 mm.

Although the manufacturing method for the support board 1 for perforation processing according to the present invention is not specifically limited, the following methods can be exemplified:

a method comprising the steps of: kneading or heat-kneading crystalline water-soluble resin and crystal nucleation agent using a kneading means, such as, e.g., a roll or a kneader, to obtain an uniform mixture, preferably a mixture having viscosities 50,000 to 200,000 mPa·s (150° C.); and then applying the mixture onto the aluminum substrate 2 by, e.g., a roll method or a curtain coat method, to thereby form a lubrication layer 3;

a method comprising the steps of: forming a mixture of crystalline water-soluble resin and crystal nucleation agent into a sheet by, e.g., a press method, a roll method, or a T die extrusion method; and adhering the sheet to the aluminum substrate 2;

a method comprising the steps of: forming a mixture of crystalline water-soluble resin and crystal nucleation agent into a sheet by, e.g., a press method, a roll method, a T-die extrusion method; superimposing the sheet on an aluminum substrate 2; and heating and pressing them;

a method comprising the steps of: forming a mixture of crystalline water-soluble resin and crystal nucleation agent into a sheet by, e.g., a press method, a roll method, a T-die extrusion method; and adhering the sheet on an aluminum substrate 2 with adhesive agent; and

a method comprising the steps of: printing a mixture formed by dissolving crystalline water-soluble resin and crystal nucleation agent in water on an aluminum substrate 2; and drying the mixture to thereby form a lubrication layer 3.

The perforation processing using the support board 1 for perforation processing of the present invention can be performed, for example, in the following manner. That is, a plurality of printed circuit raw boards are stacked on a back-up board; and on the top surface of the uppermost raw board, the support board 1 for perforation processing of the present invention is disposed with the lubrication layer surface side facing up; in this state, a perforation of a diameter 0.3 mm or less is formed in the support board and the printed circuit raw boards from above using a drill. This perforation processing method uses the support board 1 for perforation processing to perform the perforation processing, and therefore the possibility of breakage of drills can be reduced, and the positioning accuracy of the perforation can also be improved. In addition, the possibility of breakage of drills can be reduced, making it possible to increase the number of printed circuit raw boards to be stacked, which in turn can improve the productivity of the printed circuit boards. As the printed circuit raw board, a copper-clad lamination board or a multilayer board can be exemplified.

In the aforementioned embodiment, the lubrication layer is formed on one surface of the aluminum substrate. However, it is not especially limited to this structure. For example, it can be configured such that the lubrication layer is formed on both surfaces of the aluminum substrate.

Furthermore, in the aforementioned embodiment, the lubrication layer is formed directly on one surface of the aluminum substrate. However, it is not especially limited to this structure. For example, it can be configured such that the lubrication layer is formed on one side or both sides of the aluminum substrate via a priming coat. The priming coat is not specifically limited, and can be, for example, partially saponificated polyvinyl acetate.

### EXAMPLES

Next, examples of the present invention will be explained as follows, but it should be noted that the present invention is not specifically limited to these examples.

### Example 1

A mixture containing 100 mass parts of polyethylene glycol having a 10,000 number average molecular weight and 0.5 mass parts of alkyl substituted dibenzyliden sorbitol was applied to one surface (this surface is pre-coated) of a substrate having a thickness of 100 μm made of JIS A1N30-H18 material by a roll coat method to form a lubrication layer 30 μm in thickness to thereby obtain a support board for perforation processing.

### Examples 2 to 7

A support board for perforation processing was manufactured in the same manner as in EXAMPLE 1 except that a mixture containing the composition as described in Table 1 was used as the mixture.

The polyethylene glycol used in EXAMPLES 1, 2, 5, 6 and 7, the polyoxyethylene laurate used in EXAMPLE 3, and the polyethylene•polypropylene glycol used in EXAMPLE 4 are water-soluble resin corresponding to “one or more types of water-soluble resins selected from the group consisting of poryoxyethylene, polyoxyethylene propylene copolymer, and derivatives thereof”.

Also, in EXAMPLE 7, as the rosin metal salt, “PINE CRYSTAL MK-1500” (product name) manufactured by Arakawa Chemical Industries, LTD) was used.

### Comparative Examples 1 to 3

A support board for perforation processing was manufactured in the same manner as in EXAMPLE 1 except that a mixture containing the composition as described in Table 2 was used.

A variety of evaluations based on the following evaluation method were performed for each support board for perforation processing obtained as mentioned above.

<Evaluation Method for the Existence of Coated-Film Breakage of the Lubrication Layer>

By visually observing the lubrication layer of the support board for perforation processing, the existence of coated-film breakage of the lubrication layer was evaluated according to the following criteria.

### (Criteria)

“⊚” . . . no occurrence of coated-film breakage
“◯” . . . almost no occurrence of coated-film breakage
“∇” . . . slight occurrence of coated-film breakage
“X” . . . significant occurrence of coated-film breakage

<Evaluation Method of Blocking Prevention>

In a state in which the support board for perforation processing was stored in a wound manner, whether or not blocking phenomenon that the adjacent boards adhere with together (attach to each other) occurs was investigated and evaluated based on the following evaluation criteria.

### (Evaluating Criteria)

“⊚” . . . no occurrence of blocking phenomenon
“◯” . . . almost no occurrence of blocking phenomenon
“∇” . . . slight occurrence of blocking phenomenon
“X” . . . significant occurrence of blocking phenomenon

<Evaluation Method for Stickiness of Lubrication Layer>

The existence of stickiness at the time of handling the support board for perforation processing was examined and evaluated based on the following evaluation criteria.

### (Evaluation Criteria)

“⊚” . . . no occurrence of stickiness
“◯” . . . almost no occurrence of stickiness
“∇” . . . slight occurrence of stickiness
“X” . . . significant occurrence of stickiness

TABLE 1

| | | | Ex. 1 | Ex. 2 | Ex. 3 | Ex. 4 | Ex. 5 | Ex. 6 | Ex. 7 |
|---|---|---|---|---|---|---|---|---|---|
| Mixed | Crystalline | Polyethylene | 100 | — | — | — | 50 | 50 | 100 |
| compound/ | water-soluble | glycol (10,000 | | | | | | | |
| mass parts | resin | number average | | | | | | | |
| | | molecular weight) | | | | | | | |
| | | Polyethylene | — | 100 | — | — | 50 | 50 | — |
| | | glycol (100,000 | | | | | | | |
| | | number average | | | | | | | |
| | | molecular weight) | | | | | | | |
| | | Polyoxyethylene | — | — | 100 | — | — | — | — |
| | | laurate (3,000 | | | | | | | |
| | | number average | | | | | | | |
| | | molecular weight) | | | | | | | |
| | | Polyethylene•polypropylene | — | — | — | 100 | — | — | — |
| | | glycol (3,000 | | | | | | | |
| | | number average | | | | | | | |
| | | molecular weight) | | | | | | | |
| | Crystal | Alkyl substitution | 0.5 | — | — | — | — | — | — |
| | nucleation | dibenzylidene | | | | | | | |
| | agent | sorbitol | | | | | | | |
| | | Dimethylenebis | — | 1 | — | — | — | — | — |
| | | (4,6 di-t- | | | | | | | |
| | | butylphenyl | | | | | | | |
| | | sodium) | | | | | | | |
| | | Sodium stearate | — | — | 2 | — | — | — | — |
| | | Polyethylene | — | — | — | 3 | — | — | — |
| | | beads | | | | | | | |
| | | Benzoic acid | — | — | — | — | 0.3 | — | |
| | | Titanium dioxide | — | — | — | — | — | 0.3 | — |
| | | Rosin metal salt | — | — | — | — | — | — | 1.5 |

| | | | | | | | | |
|---|---|---|---|---|---|---|---|---|
| Evaluation Results | Existence of | ⊚ | ⊚ | ⊚ | ⊚ | ⊚ | ⊚ | ⊚ |
| | coated-film | | | | | | | |
| | breakage of | | | | | | | |
| | lubrication layer | | | | | | | |
| | Blocking | ⊚ | ⊚ | ⊚ | ⊚ | ⊚ | ⊚ | ⊚ |
| | Prevention | | | | | | | |
| | Stickiness of the | ⊚ | ⊚ | ⊚ | ⊚ | ⊚ | ⊚ | ⊚ |
| | lubrication layer | | | | | | | |

TABLE 2

| | | | Comp. Ex. 1 | Comp. Ex. 2 | Comp. Ex. 3 |
|---|---|---|---|---|---|
| Mixed compound/ | Crystalline water- | Polyethylene glycol (10,000 number | 100 | — | 50 |
| mass parts | soluble resin | average molecular weight) | | | |
| | | Polyethylene glycol (100,000 number | — | — | 50 |
| | | average molecular weight) | | | |
| | | Polyoxyethylene laurate (3,000 number | — | 100 | — |
| | | average molecular weight) | | | |
| | | Polyethylene•polypropylene glycol | — | — | — |
| | | (3,000 number average molecular | | | |
| | | weight) | | | |
| | Crystal nucleation | Alkyl substitution dibenzylidene sorbitol | — | — | — |
| | agent | Dimethylenebis (4,6 di-t-butylphenyl | | — | — |
| | | sodium) | | | |
| | | Sodium stearate | — | — | — |
| | | Polyethylene beads | — | — | — |
| | | Benzoic acid | — | — | — |
| | | Titanium dioxide | — | — | — |
| | | Rosin metal salt | — | — | — |

| | | | | |
|---|---|---|---|---|
| Evalution Results | Existence of breakage of lubrication | X | ◯ | X |
| | layer film coating | | | |
| | Blocking Prevention | ◯ | X | ◯ |
| | Stickiness of the lubrication layer | X | X | ◯ |

As will be apparent from Tables, the support boards for perforation processing of EXAMPLES 1 to 7 of the present invention were non-sticky, excellent in blocking prevention, and there was no occurrence of coated-film breakage of the lubrication layer.

On the other hand, in the support board for perforation processing of the COMPARATIVE EXAMPLE 1 in which the lubrication layer was made of polyethylene glycol (10,000 number average molecular weight) and no crystal nucleation agent was contained in the lubrication layer, significant coated-film breakage occurred. Furthermore, significant stickiness occurred at the time of handling the support board, and therefore the perforation processing was poor in workability. Also, in the support board for perforation processing of COMPARATIVE EXAMPLE 2 in which the lubrication layer was made of polyoxyethylene laurate and no amino acid was contained in the lubrication layer, significant blocking phenomenon occurred in a state in which the support board was stored in a wound manner. Furthermore, significant stickiness occurred at the time of handling of the support board, and therefore the perforation processing was poor in workability. Furthermore, in the support board for perforation processing of COMPARATIVE EXAMPLE 3 in which the lubrication layer was made of polyethylene glycol (10,000 number average molecular weight) and polyethylene glycol (100,000 number average molecular weight) and no crystal nucleation agent was contained in the lubrication layer, significant coated-film breakage of the lubrication layer breakage occurred.

This application claims priority to Japanese Patent Application No. 2006-279026 filed on Oct. 12, 2006, the entire disclosure of which is incorporated herein by reference in its entirety.

It should be understood that the terms and expressions used herein are used for explanation and have no intention to be used to construe in a limited manner, do not eliminate any equivalents of features shown and mentioned herein, and allow various modifications falling within the claimed scope of the present invention.

### INDUSTRIAL APPLICABILITY

The support board for perforation processing according to the present invention can be preferably used for perforation processing for various workpieces, more preferably for perforation processing in printed circuit raw boards.

1. A support board for perforation processing having a lubrication layer formed on at least one surface of an aluminum substrate,
wherein the lubrication layer is made of a mixture containing crystalline water-soluble resin and crystal nucleation agent.

2. The support board for perforation processing as recited in claim 1, wherein the crystal nucleation agent is one or more types of nucleation agents selected from the group consisting of sorbitol series nucleation agent, organic phosphate series nucleation agent, carboxylic acid metal salt series nucleation agent, rosin series nucleation agent, organic acid series nucleation agent, polymer series nucleation agent and inorganic compound series nucleation agent.

3. The support board for perforation processing as recited in claim 1, wherein the lubrication layer is made of a mixture containing 0.01 to 5 mass parts of the crystal nucleation agent with respect to 100 mass parts of the water-soluble resin.

4. The support board for perforation processing as recited in claim 1, wherein a thickness of the lubrication layer is 0.01 to 3 mm.

5. The support board for perforation processing as recited in claim 1, wherein, as the water soluble resin, one or more types of water soluble resins selected from the group consisting of polyoxyethylene, polyoxyethylene propylene copolymer, and derivatives thereof are used.

6. A support board for perforation processing having a lubrication layer formed on at least one surface of an aluminum substrate,
wherein the lubrication layer is made of a mixture containing crystalline water-soluble resin and crystal nucleation agent, and
wherein the crystal nucleation agent is one or more types of nucleation agents selected from the group consisting of sorbitol series nucleation agent, organic phosphate series nucleation agent, carboxylic acid metal salt series nucleation agent, rosin series nucleation agent, organic acid series nucleation agent, polymer series nucleation agent and inorganic compound series nucleation agent, and
wherein, as the water soluble resin, one or more types of water soluble resins selected from the group consisting of polyoxyethylene, polyoxyethylene propylene copolymer, and derivatives thereof are used.

7. The support board for perforation processing as recited in claim 6, wherein the lubrication layer is made of a mixture containing 0.01 to 5 mass parts of the crystal nucleation agent with respect to 100 mass parts of the water-soluble resin.

8. The support board for perforation processing as recited in claim 6, wherein a thickness of the lubrication layer is 0.01 to 3 mm.

9. A method of perforation processing,
wherein, in a state in which the support board for perforation processing as recited in any one of claims 1 to 8 is disposed on top of a plurality of stacked printed circuit boards, a perforation having a diameter of 0.3 mm or less is formed in the support board and the printed circuit boards from above using a drill.
